(19) United States
(12) Patent Application Publication
(10) Pub. No.: US 2014/0035123 A1
(43) Pub. Date: Feb. 6, 2014

(54) SEMICONDUCTOR DEVICE AND METHOD FOR MANUFACTURING SEMICONDUCTOR DEVICE

(71) Applicants: Seiji OKA, Tokyo (JP); Yoshihiro YAMAGUCHI, Tokyo (JP)

(72) Inventors: Seiji OKA, Tokyo (JP); Yoshihiro YAMAGUCHI, Tokyo (JP)

(73) Assignee: MITSUBISHI ELECTRIC CORPORATION, Tokyo (JP)

(21) Appl. No.: 13/829,494

(22) Filed: Mar. 14, 2013

(30) Foreign Application Priority Data
Aug. 3, 2012 (JP) 2012-172953

(51) Int. Cl. H01L 23/36; H01L 21/50

(52) U.S. Cl. CPC H01L 23/36; H01L 21/50
USPC 257/712; 438/122

(57) ABSTRACT

A semiconductor device includes: a semiconductor element; a substrate; a metal plate; and a plurality of spherical particles. The substrate has the semiconductor element mounted thereon. The metal plate has one surface and the other surface that face each other, and the substrate is provided on the one surface. The plurality of spherical particles each has a spherical outer shape, and a part of the spherical outer shape is buried in the other surface of the metal plate. With such a configuration, there can be obtained a semiconductor device that allows promotion of heat dissipation from the semiconductor element, and a method for manufacturing the semiconductor device.

### BACKGROUND OF THE INVENTION

1. Field of the Invention

The present invention relates to a semiconductor device and a method for manufacturing the semiconductor device.

2. Description of the Background Art

In a semiconductor device, a heat dissipating device such as a heat sink is used to promote heat dissipation from a heat generating body such as a semiconductor element. There has been proposed a structure for efficiently transferring heat from the heat generating body such as the semiconductor element to the heat sink to promote heat dissipation from the heat generating body such as the semiconductor element.

Japanese Patent Laying-Open No. 2006-134989, for example, discloses a structure capable of reducing a thermal resistance between electronic equipment and a heat sink. In this structure, a protrusion that is deformed by press contact is arranged on a bottom surface of a mounting plate of the electronic equipment on the side where the heat sink is attached.

In addition, Japanese Patent Laying-Open No. 2005-236266 and Japanese Patent Laying-Open No. 2005-236276, for example, disclose a substrate for a power module capable of efficiently conducting heat from the heat generating body side to the heat dissipating body side and dissipating the heat. In this substrate for the power module, a circuit layer having a semiconductor chip connected thereto and a heat sink are disposed on both sides of an insulator layer. A part of insulating highly-heat-conductive hard particles disposed in the insulator layer penetrates into both the circuit layer and the heat sink.

In the aforementioned structure disclosed in Japanese Patent Laying-Open No. 2006-134989, however, the protrusion is arranged by anchoring melted tin to a surface of the mounting plate in accordance with an ink-jet method and the like. Therefore, the protrusion is bonded to the surface of the mounting plate in a planar manner. When heat is applied to the protrusion and the mounting plate, stress may be generated at the bonded portion due to a difference in thermal expansion between the protrusion and the mounting plate, and thus, the protrusion may be peeled off from the mounting plate. If the protrusion is peeled off from the mounting plate, it becomes difficult to efficiently transfer heat from the electronic equipment serving as the heat generating body to the heat sink.

In addition, in the aforementioned substrate for the power module disclosed in Japanese Patent Laying-Open No. 2005-236266 and Japanese Patent Laying-Open No. 2005-236276, copper that is a material of the circuit layer having the semiconductor chip connected thereto is different in thermal expansion coefficient from aluminum that is a material of the heat sink, and thus, a difference in thermal expansion is produced between the circuit layer and the heat sink due to heat generation during operation of the power module. As a result, thermal stress concentrates on the insulating highly-heat-conductive hard particles. Therefore, peel-off may occur at an interface between the insulating highly-heat-conductive hard particles and the circuit layer as well as at an interface between the insulating highly-heat-conductive hard particles and the heat sink. If this peel-off occurs, it becomes difficult to efficiently transfer heat from the semiconductor chip serving as the heat generating body to the heat sink.

### SUMMARY OF THE INVENTION

The present invention has been made in view of the aforementioned problems and an object thereof is to provide a semiconductor device that allows promotion of heat dissipation from a semiconductor element, and a method for manufacturing the semiconductor device.

A semiconductor device according to the present invention includes: a semiconductor element; a substrate; a metal plate; and a plurality of spherical particles. The substrate has the semiconductor element mounted thereon. The metal plate has one surface and the other surface that face each other, and the substrate is provided on the one surface. The plurality of spherical particles each has a spherical outer shape, and a part of the spherical outer shape is buried in the other surface of the metal plate.

In the semiconductor device according to the present invention, a part of the spherical outer shape of each of the plurality of spherical particles is buried in the other surface of the metal plate. Therefore, the plurality of spherical particles cut into the other surface of the metal plate, and thus, the plurality of spherical particles can be strongly joined to the metal plate. In addition, a contact area between each of the plurality of spherical particles and the metal plate can be increased. Therefore, peel-off of the plurality of spherical particles from the metal plate can be suppressed. Accordingly, heat of the semiconductor element can be dissipated from the plurality of spherical particles.

In addition, since each of the plurality of spherical particles has the spherical outer shape, the plurality of spherical particles do not penetrate into a heat sink when the heat sink is attached. Therefore, generation of thermal stress between the plurality of spherical particles and the heat sink can be suppressed. As a result, occurrence of separation at an interface between the plurality of spherical particles and the metal plate as well as at an interface between the plurality of spherical particles and the heat sink can be suppressed. Thus, heat dissipation from the semiconductor element can be promoted.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross-sectional view of a semiconductor device according to an embodiment of the present invention.

FIG. 2 is a schematic bottom view of the semiconductor device according to the embodiment of the present invention.

FIG. 3 is an enlarged view of a P1 portion in FIG. 1.

FIG. 4 is an enlarged perspective view of a P2 portion in FIG. 2.

FIG. 5 is a schematic cross-sectional view showing one step of a method for manufacturing the semiconductor device according to the embodiment of the present invention.

FIG. 6 is a schematic cross-sectional view showing the next step to the step shown in FIG. 5.

FIG. 7 is a schematic enlarged cross-sectional view showing a structure around a plurality of spherical particles in a semiconductor device according to a modification of the embodiment of the present invention.

FIG. 8 is a schematic cross-sectional view of the semiconductor device according to the embodiment of the present invention, to which a heat sink is attached.

FIG. 9 is an enlarged view of a P3 portion in FIG. 8.

FIG. 10 is a schematic enlarged cross-sectional view showing a structure around a metal plate and a protrusion according to a comparative example.

FIG. 11 is a schematic enlarged cross-sectional view showing a structure around a metal plate and a plurality of spherical particles according to the embodiment of the present invention.

### DESCRIPTION OF THE PREFERRED EMBODIMENTS

An embodiment of the present invention will be described hereinafter with reference to the drawings.

A configuration of a semiconductor device according to the embodiment of the present invention will be first described.

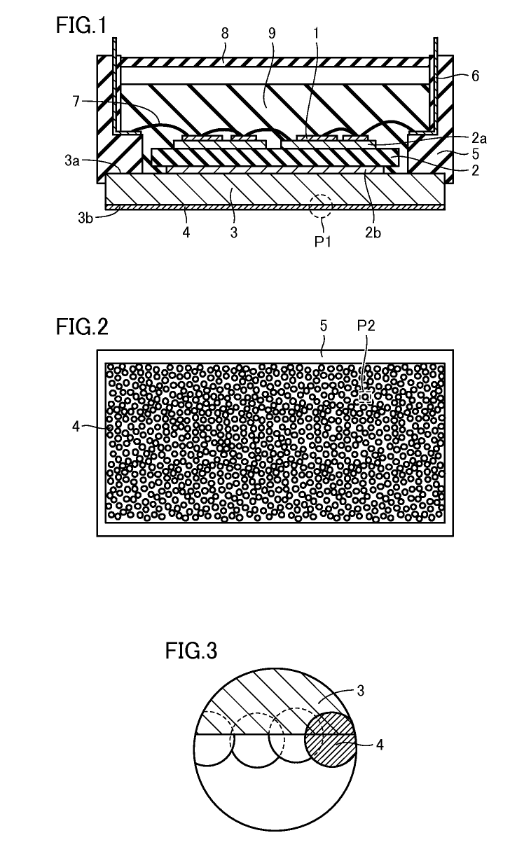

Referring to FIGS. 1 and 2, the semiconductor device according to the present embodiment is, for example, a power module. The semiconductor device according to the present embodiment mainly has a semiconductor element 1, a substrate 2, a metal plate 3, a plurality of spherical particles 4, a case 5, an electrode terminal 6, a wire 7, a lid 8, and a sealing resin 9. In FIG. 1, the plurality of spherical particles 4 are shown in a simplified manner to make the figure easy to view.

Semiconductor element 1 is, for example, a power semiconductor element. Substrate 2 is, for example, a ceramic substrate. Semiconductor element 1 is mounted on substrate 2. Semiconductor element 1 is soldered onto a pattern portion 2a provided on substrate 2.

Metal plate 3 has one surface 3a and the other surface 3b that face each other. Substrate 2 is provided on one surface 3a of metal plate 3. Substrate 2 and metal plate 3 are connected by solder 2b. Metal plate 3 is for enhancing the heat dissipation property. Metal plate 3 is made of, for example, copper or aluminum.

The plurality of spherical particles 4 are provided on the other surface 3b of metal plate 3. The plurality of spherical particles 4 are arranged over the entirety of the other surface 3b of metal plate 3. A gap may be formed between spherical particles 4. The plurality of these spherical particles 4 will be described in detail below.

Case 5 is formed around one surface 3a of metal plate 3. Case 5 is made of, for example, a resin. Electrode terminal 6 is attached to case 5. Electrode terminal 6 is formed to protrude outward from case 5. Wire 7 is, for example, an aluminum wire. Semiconductor elements 1 are electrically connected by wire 7. Semiconductor element 1 and electrode terminal 6 attached to case 5 are also electrically connected by wire 7. Lid 8 is placed at an upper end of case 5. Lid 8 is for preventing entry of dust and water.

Semiconductor element 1, substrate 2 and wire 7 are disposed in an internal space surrounded by metal plate 3, case 5 and lid 8. In the internal space, semiconductor element 1, substrate 2 and wire 7 are covered with sealing resin 9. Sealing resin 9 is, for example, a silicone gel.

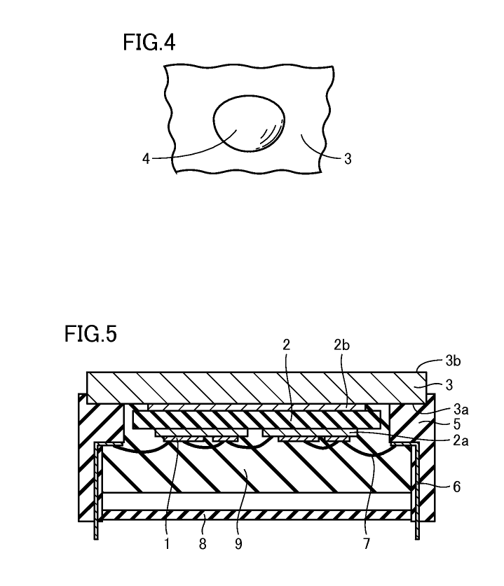

The plurality of spherical particles 4 will be described in more detail with reference to FIGS. 3 and 4. Each of the plurality of spherical particles 4 has a spherical outer shape. A part of the spherical outer shape of each of the plurality of spherical particles 4 is buried in the other surface 3b of metal plate 3. Each of the plurality of spherical particles 4 protrudes from the other surface 3b, with a part of the spherical outer shape thereof buried in the other surface 3b of metal plate 3. Each of the plurality of spherical particles 4 is arranged on the other surface 3b, with a part of the spherical outer shape thereof buried in the other surface 3b of metal plate 3.

Since a part of spherical particle 4 is buried in the other surface 3b of metal plate 3, spherical particle 4 cuts into metal plate 3, and thereby peel-off of spherical particle 4 from metal plate 3 can be suppressed. In other words, an anchor effect is obtained from this buried structure. Therefore, reliability of bonding between metal plate 3 and spherical particle 4 is enhanced.

In addition, since the spherical outer shape of spherical particle 4 is buried in the other surface 3b of metal plate 3, spherical particle 4 is in contact with metal plate 3 in a manner of the spherical outer shape. Therefore, a sufficient contact area can be ensured between spherical particle 4 and metal plate 3. As a result, the adhesion between spherical particle 4 and metal plate 3 can be ensured. Thus, the joining strength between spherical particle 4 and metal plate 3 can be increased.

In addition, since the spherical outer shape of spherical particle 4 is buried in the other surface 3b of metal plate 3, a sufficient contact area can be ensured between spherical particle 4 and metal plate 3. Therefore, the heat conducting property from metal plate 3 to spherical particle 4 is enhanced.

Preferably, the plurality of spherical particles 4 protrude from the other surface 3b in a hemispherical manner. As a result, a dense arrangement can be formed on the other surface 3b of metal plate 3. In addition, it is easy to arrange the plurality of spherical particles 4 on the other surface 3b of metal plate 3 with fewer gaps among the plurality of spherical particles 4. Therefore, heat of metal plate 3 can be diffused over the entirety of the other surface 3b.

The plurality of spherical particles 4 are made of a material having an excellent heat conducting property. Spherical particles 4 are made of, for example, metal. When metal plate 3 is made of copper, copper, nickel and iron can be used as a material of spherical particles 4. Furthermore, a copper alloy such as phosphor bronze and beryllium copper can be used. When metal plate 3 is made of aluminum, brass can also be used, in addition to the above materials.

The plurality of spherical particles 4 have a hardness higher than that of metal plate 3. Preferably, the plurality of spherical particles 4 have a Vickers hardness (Hv) of 150 or higher. Since spherical particles 4 have a hardness higher than that of metal plate 3, a part of spherical particle 4 can be buried in metal plate 3 by a spray method.

A height of spherical particle 4 from the other surface 3b is desirably 30 μm or higher and 150 μm or lower. If the height is less than 30 μm, spherical particle 4 has a particle size of approximately 40 to 60 μm, and thus, it becomes difficult to form a uniform layer on metal plate 3 because the particle is too small. If the height exceeds 150 μm, a density of spherical particles 4 on the other surface 3b of metal plate 3 becomes too low and an interval between metal plate 3 and a heat sink becomes too large, and thus, an effect of a low thermal resistance is not sufficiently obtained.

Next, a method for manufacturing the semiconductor device according to the present embodiment will be described.

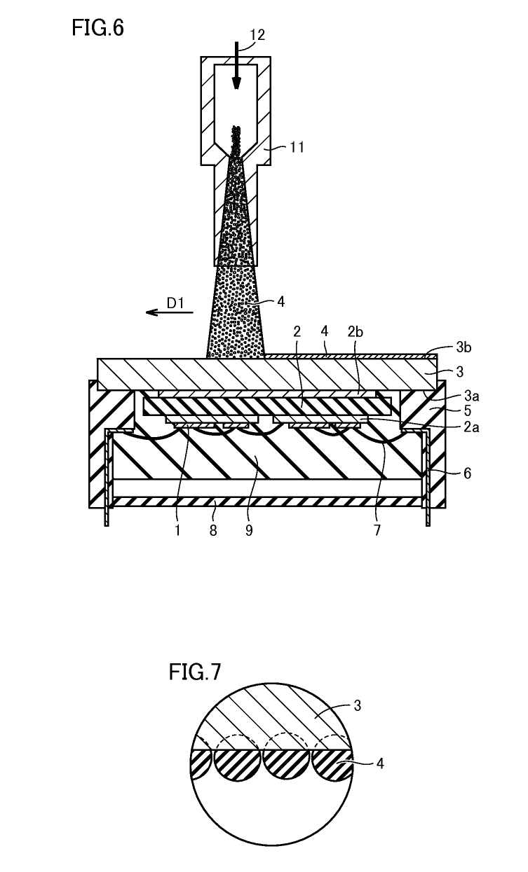

Referring to FIG. 5, prepared first is metal plate 3 having one surface 3a on which substrate 2 having semiconductor element 1 mounted thereon is provided. Next, referring to FIG. 6, the plurality of spherical particles 4 are sprayed onto the other surface 3b of metal plate 3 that faces one surface 3a of metal plate 3. The plurality of spherical particles 4 each has the spherical outer shape and have a hardness higher than that of metal plate 3. The plurality of spherical particles 4 are accelerated to a sound speed level and sprayed onto the other surface 3b of metal plate 3 from a nozzle 11 by, for example, a high-temperature and high-voltage gas 12.

Then, by moving nozzle 11 in a direction D1 along the other surface 3b of metal plate 3, the plurality of spherical particles 4 are sprayed over the entirety of the other surface 3b. The plurality of these spherical particles 4 are sprayed onto the other surface 3b of metal plate 3, and thereby a part of the spherical outer shape of each of the plurality of spherical particles 4 is buried in the other surface 3b of metal plate 3.

This spray method is a method for spraying spherical particles 4 with an initial shape maintained. A cold spray method is also one type of this spray method. By using such a spray method, the manufacturing process can be simplified and cost reduction can be achieved because there is no need to apply pressure to and heat metal plate 3.

From the viewpoint of heat conduction, it is desirable to form one layer of spherical particles 4 on metal plate 3. Since a speed of spherical particles 4 during spraying is high, spherical particles 4 may again be deposited on or adhere to formed spherical particles 4, depending on spray conditions. In order to avoid this, the temperature and the flow rate (pressure) during spraying are preferably controlled.

Although the case where spherical particles 4 are made of metal has been described in the foregoing, the material of spherical particles 4 is not limited to the metal. Referring to FIG. 7, spherical particles 4 are made of ceramic in a modification of the present embodiment.

A material having an excellent heat conducting property, such as aluminum oxide, aluminum nitride, silicon nitride, silicon carbide, and silicon oxide, can be used as ceramic spherical particles 4. Since ceramic spherical particles 4 generally have a hardness higher than that of metal, an outer shape thereof is not deformed by the spray method under the high-temperature and high-voltage gas, and one uniform layer of the spherical particles with substantially the same height is densely formed on the other surface 3b of metal plate 3. Therefore, the uniform heat conducting property can be achieved over the entirety of the other surface 3b of metal plate 3, although ceramic is lower in heat conductivity than metal.

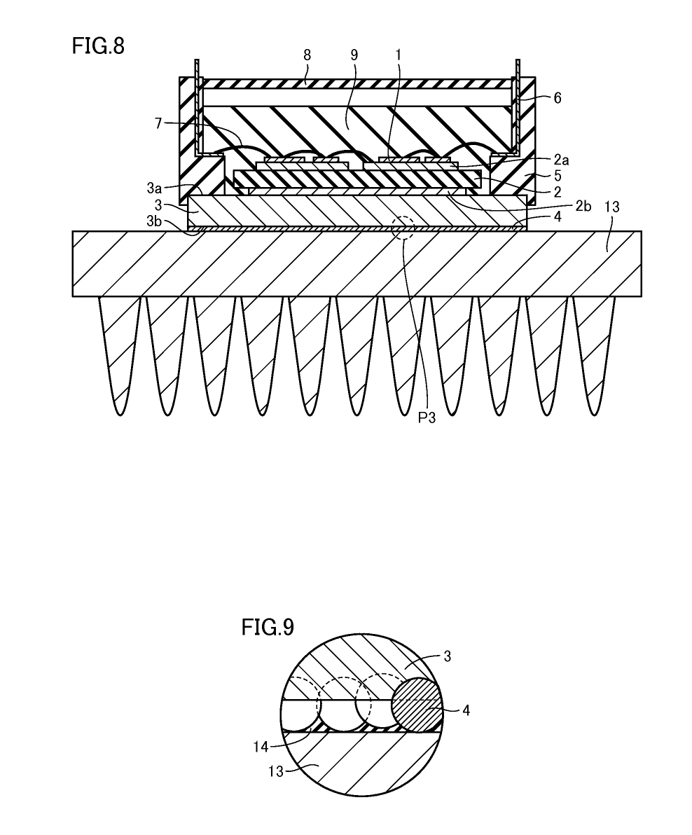

Next, a configuration of the semiconductor device having a heat sink attached thereto will be described with reference to FIGS. 8 and 9.

A heat sink 13 is attached to the other surface 3b of metal plate 3 with the plurality of spherical particles 4 and grease 14 interposed therebetween. Thermal grease is used as grease 14. When grease 14 is not interposed between the other surface 3b of metal plate 3 and heat sink 13, an air layer is present between the plurality of spherical particles 4 and heat sink 13, and thus, heat conduction is blocked. On the other hand, by the presence of grease 14 in the air gap as in the present embodiment, the heat conducting property can be enhanced. Therefore, a low thermal resistance of the semiconductor device can be achieved. In addition, metal plate 3 can be fixed to heat sink 13 by grease 14.

The heat conducting property of the semiconductor device becomes better as the heat conductivity of grease 14 becomes higher. However, even in the case of grease 14 having a heat conductivity of approximately 1 W/mK, which is commonly used, the heat conducting property is enhanced as compared with conventional structures because of the plurality of spherical particles 4.

Grease 14 may be applied on the metal plate 3 side or on the heat sink 13 side. In order not to interpose the air layer between metal plate 3 and heat sink 13, application of grease 14 on the metal plate 3 side beforehand is more effective.

The plurality of spherical particles 4 are in contact with heat sink 13, but are not buried in heat sink 13. Since the plurality of spherical particles 4 are in contact with heat sink 13 as described above, thermal stress is not generated between the plurality of spherical particles 4 and heat sink 13 even if the temperature changes during heat generation in semiconductor element 1. Therefore, the plurality of spherical particles 4 have a stable low thermal resistance. In addition, there is no damage to a surface of heat sink 13 caused by the plurality of spherical particles 4 buried in heat sink 13. Therefore, heat sink 13 can be repeatedly used. Accordingly, the repair property of heat sink 13 can be achieved.

The configuration of the semiconductor device according to the present embodiment is not limited to the above-described configuration. A metal substrate using a resin insulating sheet may be used instead of the ceramic substrate. The semiconductor device may also be configured such that metal plate 3 is not joined to the ceramic substrate and a metal plate provided on the opposite side of the pattern portion of the ceramic substrate is exposed at the bottom surface.

Next, functions and effects of the present embodiment will be described in contrast with those of a comparative example.

Referring to FIG. 10, in the comparative example, a surface of copper metal plate 3 is plated with gold and a protrusion 20 is anchored and arranged on the surface. The gold plate is not shown to make the figure easy to view. This protrusion 20 is formed by jetting melted tin from a nozzle like an ink-jet. In this comparative example, protrusion 20 is anchored by spraying the melted tin, and thus, protrusion 20 is not buried in metal plate 3 but adheres to the surface of metal plate 3. Therefore, protrusion 20 is bonded to metal plate 3 in a planar manner.

Therefore, it is difficult to join protrusion 20 and metal plate 3 strongly. It is also difficult to increase a contact area A between protrusion 20 and metal plate 3. In the comparative example, when heat is applied to protrusion 20 and metal plate 3, thermal stress is generated at the contact portion between protrusion 20 and metal plate 3 due to a difference in thermal expansion between protrusion 20 and metal plate 3, and thus, protrusion 20 is more likely to be peeled off from metal plate 3.

In addition, in the comparative example, the melted tin is sprayed, and thus, it is difficult to form protrusion 20 having a uniform shape. Furthermore, protrusion 20 is formed on the surface of metal plate 3, and thus, reliability of bonding between metal plate 3 and protrusion 20 due to uniformity and the like of surface treatment for the underlying metal is low. Moreover, in the comparative example, pretreatment such as gold plating is necessary and it takes time to solidify the melted tin, which requires a long time for manufacturing and leads to increase in cost of the manufacturing process.

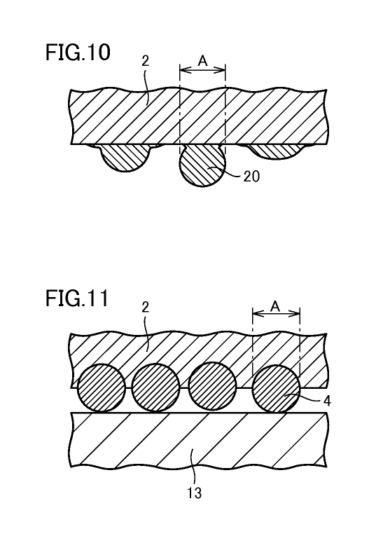

On the other hand, referring to FIG. 11, in the semiconductor device according to the present embodiment, a part of the spherical outer shape of each of the plurality of spherical particles 4 is buried in the other surface 3b of metal plate 3. Therefore, the plurality of spherical particles 4 cut into the other surface 3b of metal plate 3, and thus, the plurality of spherical particles 4 can be strongly joined to metal plate 3. In addition, a contact area A between each of the plurality of spherical particles 4 and metal plate 3 can be increased. Therefore, peel-off of the plurality of spherical particles 4 from metal plate 3 can be suppressed. Accordingly, heat of semiconductor element 1 can be dissipated from the plurality of spherical particles 4.

In addition, since each of the plurality of spherical particles 4 has the spherical outer shape, the plurality of spherical particles 4 do not penetrate into heat sink 13 when heat sink 13 is attached. Therefore, generation of thermal stress between the plurality of spherical particles 4 and heat sink 13 can be suppressed. As a result, occurrence of separation at an interface between the plurality of spherical particles 4 and metal plate 3 as well as at an interface between the plurality of spherical particles 4 and heat sink 13 can be suppressed. Thus, heat dissipation from semiconductor element 1 can be promoted.

In the semiconductor device according to the present embodiment, spherical particles 4 are made of metal, and thus, spherical particles 4 have an excellent heat conducting property. Therefore, heat dissipation from semiconductor element 1 can be promoted.

In the semiconductor device according to the modification of the present embodiment, spherical particles 4 are made of ceramic, and thus, spherical particles 4 have a hardness higher than that of metal. Therefore, in the state where spherical particles 4 are buried in metal plate 3, deformation of the outer shape can be suppressed. Accordingly, spherical particles 4 can be uniformly arranged on the other surface 3b of metal plate 3. As a result, the uniform thermoelectric property can be achieved over the entirety of the other surface 3b of metal plate 3.

In the semiconductor device according to the present embodiment, heat sink 13 is attached to the other surface 3b of metal plate 3 with the plurality of spherical particles 4 and grease 14 interposed therebetween. Therefore, heat conduction from spherical particles 4 to heat sink 13 can be promoted. As a result, heat dissipation from spherical particles 4 can be promoted.

In addition, since the plurality of spherical particles 4 are in contact with heat sink 13 but are not buried in heat sink 13, thermal stress is not generated between the plurality of spherical particles 4 and heat sink 13 even if the temperature changes during heat generation in semiconductor element 1. In addition, there is no damage to the surface of heat sink 13 caused by the plurality of spherical particles 4 buried in heat sink 13. Therefore, heat sink 13 can be repeatedly used. Accordingly, the repair property of heat sink 13 can be achieved.

In the method for manufacturing the semiconductor device according to the present embodiment, spherical particles 4 having a hardness higher than that of metal plate 3 are sprayed onto the other surface 3b of metal plate 3, and thereby a part of the spherical outer shape of each spherical particle 4 is buried in the other surface 3b of metal plate 3.

Therefore, the plurality of spherical particles 4 can be buried in the other surface 3b of metal plate 3. In addition, the plurality of spherical particles 4 can be formed to have a uniform shape on the other surface 3b of metal plate 3. Furthermore, surface treatment for the underlying metal of metal plate 3 is unnecessary, and thus, reliability of bonding can be enhanced. Moreover, pretreatment such as gold plating is unnecessary and a time to solidify spherical particles 4 is also unnecessary, which leads to reduction in time and cost of the manufacturing process.

Although the present invention has been described and illustrated in detail, it is clearly understood that the same is by way of illustration and example only and is not to be taken by way of limitation, the scope of the present invention being interpreted by the terms of the appended claims.

What is claimed is:

1. A semiconductor device, comprising:
a semiconductor element;
a substrate having said semiconductor element mounted thereon;
a metal plate having one surface and the other surface that face each other, said substrate being provided on said one surface; and
a plurality of spherical particles each having a spherical outer shape, a part of said spherical outer shape being buried in said other surface of said metal plate.

2. The semiconductor device according to claim 1, wherein
said spherical particles are made of metal.

3. The semiconductor device according to claim 1, wherein
said spherical particles are made of ceramic.

4. The semiconductor device according to claim 1, wherein
a heat sink is attached to said other surface of said metal plate with said plurality of spherical particles and grease interposed therebetween.

5. A method for manufacturing a semiconductor device, comprising the steps of:
preparing a metal plate having one surface on which a substrate having a semiconductor element mounted thereon is provided; and
spraying a plurality of spherical particles each having a spherical outer shape and having a hardness higher than that of said metal plate onto the other surface of said metal plate that faces said one surface of said metal plate, thereby burying a part of said spherical outer shape of each of said plurality of spherical particles in said other surface of said metal plate.
